(19) United States
(12) Patent Application Publication
(10) Pub. No.: US 2017/0156231 A1
(43) Pub. Date: Jun. 1, 2017

(54) SOUNDBOX

(71) Applicants: LE HOLDINGS (BEIJING) CO., LTD., Beijing (CN); LE SHI ZHI XIN ELECTRONIC TECHNOLOGY (TIANJIN) LIMITED, Beijing (CN)

(72) Inventors: Peifeng GAO, Beijing (CN); Shiming QING, Beijing (CN); Feng SUN, Beijing (CN)

(21) Appl. No.: 15/239,188

(22) Filed: Aug. 17, 2016

Related U.S. Application Data
(63) Continuation of application No. PCT/CN2016/083047, filed on May 23, 2016.

(30) Foreign Application Priority Data
Nov. 30, 2015 (CN) 2015209778615

(51) Int. Cl. H05K 7/14

(52) U.S. Cl. CPC H05K 7/1434; H05K 7/1418

(57) ABSTRACT

A soundbox is disclosed in the embodiments of the disclosure, wherein the soundbox comprises a soundbox main body, an easily-easily-detachable guiding device is arranged on the soundbox main body (1), the easily-detachable guiding device comprises PCB plate fixed mount (3) and PCB plates (2), the PCB plates (2) are fixed in the inner side of the PCB plate fixed mount (3), and the PCB plates (2) are placed within the soundbox main body (1) by connecting the PCB plate fixed mount (3) and soundbox main body (1).

### CROSS REFERENCE TO RELATED APPLICATIONS

This application is a continuation of International Application No. PCT/CN2016/083047, filed on May 23, 2016, which is based upon and claims priority to Chinese Patent Application No. 201520977861.5, filed on Nov. 30, 2015, the entire contents of which are incorporated herein by reference.

### TECHNICAL FIELD

The disclosure relates to a soundbar, particularly to an easily-detachable guiding device for the PCB plates in a soundbar.

### BACKGROUND

In the present soundbox field of soundbar and smart soundbar, internal PCB plates are directly fixed within the interior of the cavity when designing internal structure. Therefore, it is not facilitated to detach for upgrading the hardware and maintaining.

As shown in FIG. 1, the internal PCB plates of the existing soundbar are fixed within the interior of the main body of the soundbar by screw, and then the fixed cover 6, the iron net or the appearance decorating parts is fitted for decorating. The appearance decorating parts and the alike need to be removed when the soundbar is detached for upgrading or maintaining, while removing is complicated and easily leads to damage to the appearance. With the development of the soundbar and smart soundbar, consumers pay more and more attentions to their appearance and properties, and the soundbar needs to be upgraded and updated. At present, it is hard to satisfy the future development tendency with those technical solutions above.

### SUMMARY

The object of the embodiments of the disclosure is to provide a soundbox with an easily-detachable guiding device.

In order to achieve the object above, the soundbox according to the embodiments of the disclosure includes a soundbox main body, wherein an easily-easily-detachable guiding device is arranged on the soundbox main body, the easily-detachable guiding device comprises PCB plate fixed mount and PCB plates, the PCB plates are fixed in the inner side of the PCB plate fixed mount, and the PCB plates are placed within the soundbox main body by connecting the PCB plate fixed mount and soundbox main body.

Further, the fixed mount guiding pillars are arranged on the both ends of the PCB plate fixed mount, the guiding sleeves that can accommodate the fixed mount guiding pillars are arranged within the soundbox main body, and the fixed mount guiding pillars are inserted into the guiding sleeves so as to connect the PCB plate fixed mount with the soundbox main body together.

Further, a first through hole is arranged on the soundbox main body, a second through hole is arranged on the PCB plate fixed mount, and a fixer passes through the first through hole and the second through hole so as to fixedly connect the PCB plate fixed mount with the soundbox main body together.

Further, guiding sleeves in the soundbox main body are arranged in the position corresponding to the fixed mount guiding pillars on the PCB plate fixed mount.

Further, the fixed mount guiding pillars are projected cylindrical posts.

Further, the guiding sleeves are projected cylindrical posts, and grooves which can receive the fixed mount guiding pillars are arranged inside the guiding sleeves.

Further, the PCB plate fixed mount is arc-shaped and have recess portion in the middle.

Further, the PCB plate is fixed on the recess portion in the middle of the PCB plate fixed mount.

Further, the soundbox main body is hollow cylindrical, and the soundbox main body and the PCB plate fixed mount are assembled together to form the whole cylinder.

The advantages of the soundbox according to the embodiments of the disclosure is that, when it is needed to detach the soundbox to do upgrading or maintenance, it is needed only to detach the screw fastened to the PCB plate fixed mount and pull the screw out along the direction of the guiding pillars, therefore, it is simple and convenient to detach and is not easy to damage the appearance, which can meet the requirements of consumers for its appearance and performance.

### BRIEF DESCRIPTION OF THE DRAWINGS

By reading the detailed description of the preferably selected embodiments below, various other advantages and benefits become clear for a person of ordinary skill in the art. The drawings are only used for showing the purpose of the preferred embodiments and are not intended to limit the present invention. And in the whole drawings, the same drawing reference signs are used for representing the same components. In the drawings:

FIG. 1 is a structural schematic view of the existing fixing device for the PCB plate;

FIG. 2 is a structural schematic view of the easily-detachable guiding device of the present invention.

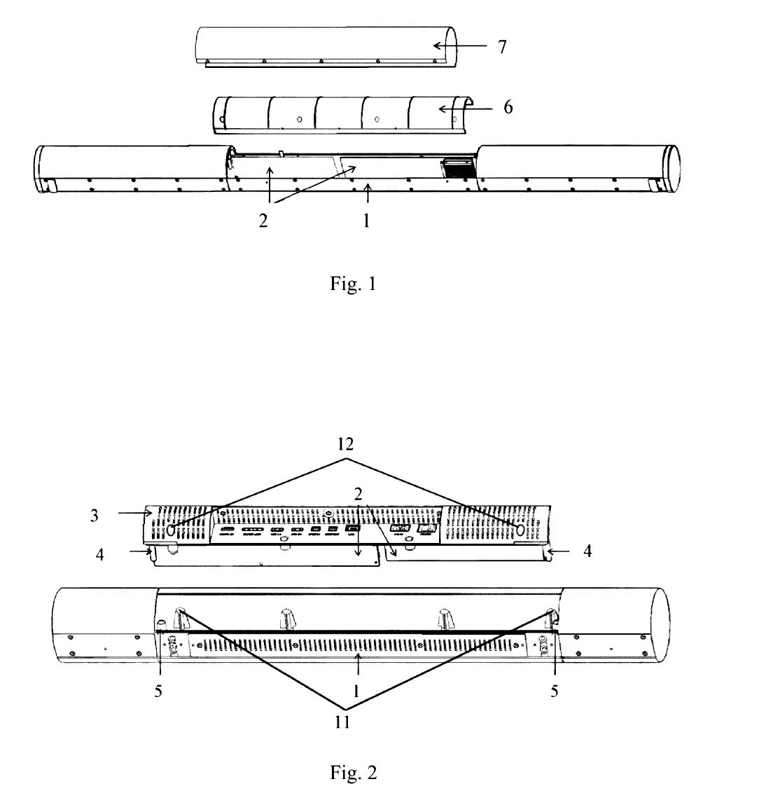

### DETAILED DESCRIPTION

The embodiments of the disclosure will be described in further detail with reference to the drawings below. However, it should be understood that the disclosure may be implemented in various ways and is not limited by embodiments set forth herein. Instead, those embodiments are provided so that the disclosure will be understood more thoroughly and the scope of the disclosure will be fully conveyed to the skill person in the art.

The embodiments of the disclosure disclose a soundbox. As shown in FIG. 2, the soundbox includes a soundbox main body. An easily-detachable guiding device is arranged on the soundbox main body 1. The easily-detachable guiding device includes PCB plate fixed mount 3 and PCB plates 2. The PCB plates 2 are fixed in the inner side of the PCB plate fixed mount 3. The PCB plates 2 are placed within the soundbox main body 1 by connecting the PCB plate fixed mount 3 and soundbox main body 1. Wherein, the fixed mount guiding pillars 4 are arranged on the both ends of the PCB plate fixed mount 3, the guiding sleeves 5 for accommodating the fixed mount guiding pillars 4 are arranged within the soundbox main body 1, and the fixed mount guiding pillars 4 are inserted into the guiding sleeves 5 so as to connect the PCB plate fixed mount 3 with the soundbox main body 1 together.

In order to fixedly connect the soundbox main body 1 with the PCB plate fixed mount 3, a first through hole 11 is arranged on the soundbox main body 1, and a second through hole 12 is arranged on the PCB plate fixed mount 3. A fixer passes through the first through hole 11 and the second through hole 12 so as to fixedly connect the PCB plate fixed mount 3 with the soundbox main body 1 together. The fixer can be screw. When it is needed to upgrade the hardware and do maintenance, people can only disassemble the screw fastened to the PCB plate fixed mount 3 and pull the fixed mount guiding pillars 4 out of the guiding sleeves 5 along the direction of the guiding pillars.

Furthermore, the fixed mount guiding pillars 4 are located on the PCB plate fixed mount 3 which is on same side with the PCB plates 2. The fixed mount guiding pillars 4 are close to the edges of the both ends of the PCB plate fixed mount. The fixed mount guiding pillars 4 are projected cylindrical posts. The guiding sleeves 5 within the soundbox main body 1 are also cylindrical posts which are projected. And the grooves which can receive the fixed mount guiding pillars 4 are arranged in the guiding sleeves. The guiding sleeves are arranged in the position which corresponds to the fixed mount guiding pillars 4 on the PCB plate fixed mount. The fixed mount guiding pillars 4 may be inserted into the groove of the guiding sleeves 5 on the soundbox main body so as to fix the PCB plate 2 within the soundbox main body. Wherein, the PCB plate 2 of the disclosure include power board, power amplification board and main board etc., and the PCB plate mentioned above are all fixed on the PCB plate fixed mount 3.

Furthermore, the PCB plate fixed mount is arc-shaped and have recess portion in the middle along the vertical direction. Specifically, the PCB plate 2 is fixed on the middle recess portion of the PCB plate fixed mount. In addition, the soundbox main body 1 is hollow cylinder, and the soundbox main body 1 and the PCB plate fixed mount 3 are assembled together to form the whole cylinder.

With the soundbox of the disclosure, when it is needed to detach the soundbox to do upgrading or maintenance, it is needed only to detach the screw fastened to the PCB plate fixed mount and pull the screw out along the direction of the guiding pillars. Therefore, it is simple and convenient to detach and is not easy to damage the appearance, which can meet the requirements of consumers for its appearance and performance.

The further description is made by means of the specific embodiment above, however, it should be understood that the description herein should not be construed to limit the scope and the substance of the present invent. The various modifications to embodiments above that the skills in the art make after reading the specification are within the scope of the claimed invention.

1-9. (canceled)

10. A soundbox, wherein the soundbox comprises a soundbox main body, an easily-easily-detachable guiding device is arranged on the soundbox main body, the easily-detachable guiding device comprises PCB plate fixed mount and PCB plates, the PCB plates are fixed in the inner side of the PCB plate fixed mount, and the PCB plates are placed within the soundbox main body by connecting the PCB plate fixed mount and soundbox main body.

11. The soundbox according to claim 10, wherein the fixed mount guiding pillars are arranged on the both ends of the PCB plate fixed mount, the guiding sleeves that can accommodate the fixed mount guiding pillars are arranged within the soundbox main body, and the fixed mount guiding pillars are inserted into the guiding sleeves so as to connect the PCB plate fixed mount with the soundbox main body together.

12. The soundbox according to claim 10, wherein a first through hole is arranged on the soundbox main body, a second through hole is arranged on the PCB plate fixed mount, and a fixer passes through the first through hole and the second through hole so as to fixedly connect the PCB plate fixed mount with the soundbox main body together.

13. The soundbox according to claim 10, wherein guiding sleeves in the soundbox main body are arranged in the position corresponding to the fixed mount guiding pillars on the PCB plate fixed mount.

14. The soundbox according to claim 10, wherein the fixed mount guiding pillars are projected cylindrical posts.

15. The soundbox according to claim 10, wherein the guiding sleeves are projected cylindrical posts, and grooves which can receive the fixed mount guiding pillars are arranged inside the guiding sleeves.

16. The soundbox according to claim 10, wherein the PCB plate fixed mount is arc-shaped and have recess portion in the middle.

17. The soundbox according to claim 16, wherein the PCB plate is fixed on the recess portion in the middle of the PCB plate fixed mount.

18. The soundbox according to claim 10, wherein the soundbox main body is hollow cylindrical, and the soundbox main body and the PCB plate fixed mount are assembled together to form the whole cylinder.
